(19) United States
(12) Patent Application Publication
(10) Pub. No.: US 2007/0290260 A1
(43) Pub. Date: Dec. 20, 2007

(54) Trench Type Mosfet And Method Of Fabricating The Same

(76) Inventor: Alberto O. Adan, Nara (JP)

Correspondence Address: HARNESS, DICKEY & PIERCE, P.L.C., P.O. BOX 8910, RESTON, VA, 20195, US

(21) Appl. No.: 11/794,352

(22) PCT Filed: Jun. 7, 2006
(86) PCT No.: PCT/JP06/11447

§ 371 Date: Jun. 28, 2007

(30) Foreign Application Priority Data
Jun. 8, 2005 (JP) 2005-168790

(51) Int. Cl. H01L 29/78; H01L 21/336

(52) U.S. Cl. 257/330; 438/270; 257/E29.255; 257/E21.409

(57) ABSTRACT

A Trench MOSFET of an embodiment of the present invention includes: a semiconductor substrate including a substrate, an epitaxial layer, a body region, and a highly doped source region. The substrate, the epitaxial layer, the body region, and the highly doped source region are adjacently formed in this order. A trench region is formed in the semiconductor substrate in such a manner that the bottom of the trench region reaches the epitaxial layer. A gate insulator is formed on a bottom surface and a sidewall of the trench region. A gate electrode is provided within the trench region. The gate insulator includes an electric-field reducer thicker than a thickness of the gate insulator provided between the gate electrode and the body region. Thus, voltage-resistance improves in the vicinity of the bottom of the trench. This allows increase of breakdown voltage. Therefore, a Trench MOSFET with higher breakdown voltage is realized.

### TECHNICAL FIELD

The present invention relates to the structure and manufacturing of semiconductor devices, and particularly to a Trench MOSFET (Metal Oxide Semiconductor Field Effect Transistor) that is useful in power applications and has high breakdown voltage. The present invention also relates to a method of fabricating the Trench MOSFET.

### BACKGROUND ART

The Trench-type Vertical MOSFET, or simply Trench MOS, is widely used in power control electronics due to their efficient structure and low specific ON resistance.

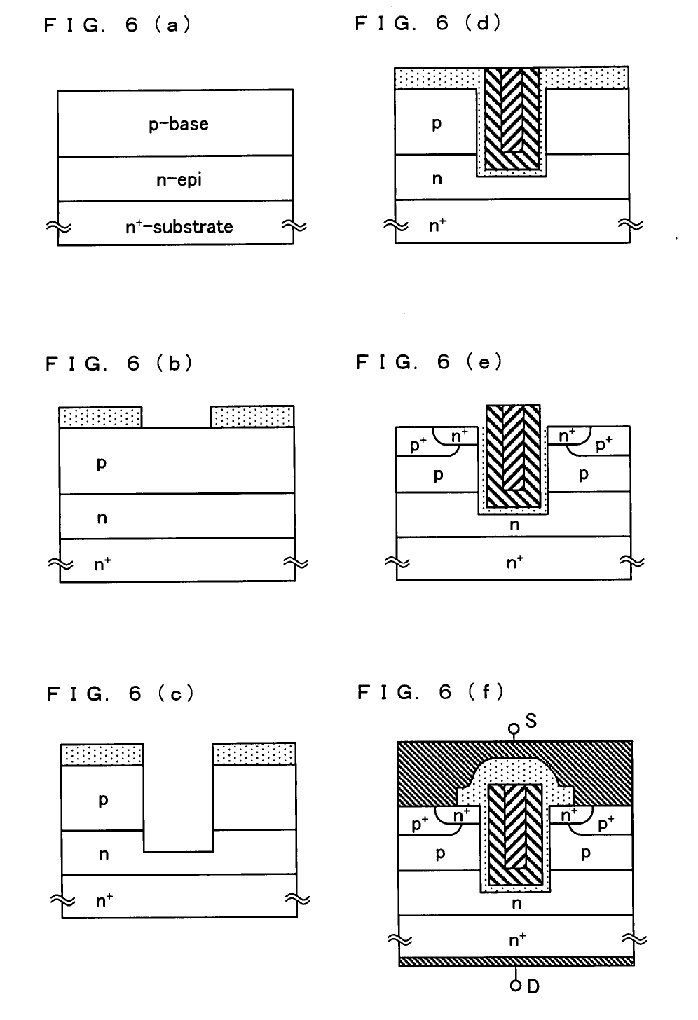

FIGS. 6(a) to 6(f) are cross-sectional diagrams illustrating the steps of producing the prior art typical structure of a N-channel Trench MOSFET (see Non-Patent Reference 1, for example). FIG. 6(a) shows a step in which an Epi layer (n-epi) and a body region (diffusion, p-base) are formed. FIG. 6(b) shows a step in which a SiO₂ opening is formed. FIG. 6(c) shows a step in which the trench is fabricated with the opening in FIG. 6(b) to define the etching. FIG. 6(d) shows a step in which the trench is filled with polysilicon deposition and etched back. FIG. 6(e) shows a step in which oxide is etched, and N+ (source region) and P+ (body region) are implanted. FIG. 6(f) shows a step in which interlevel dielectric deposition and metallization are carried out.

Two key parameters in the Trench MOSFET are (a) the breakdown voltage (hereinafter, the voltage will sometimes be referred to as “BVdss”), and (b) the ON resistance (hereinafter, the resistance will sometimes be referred to as “R_{ON}”).

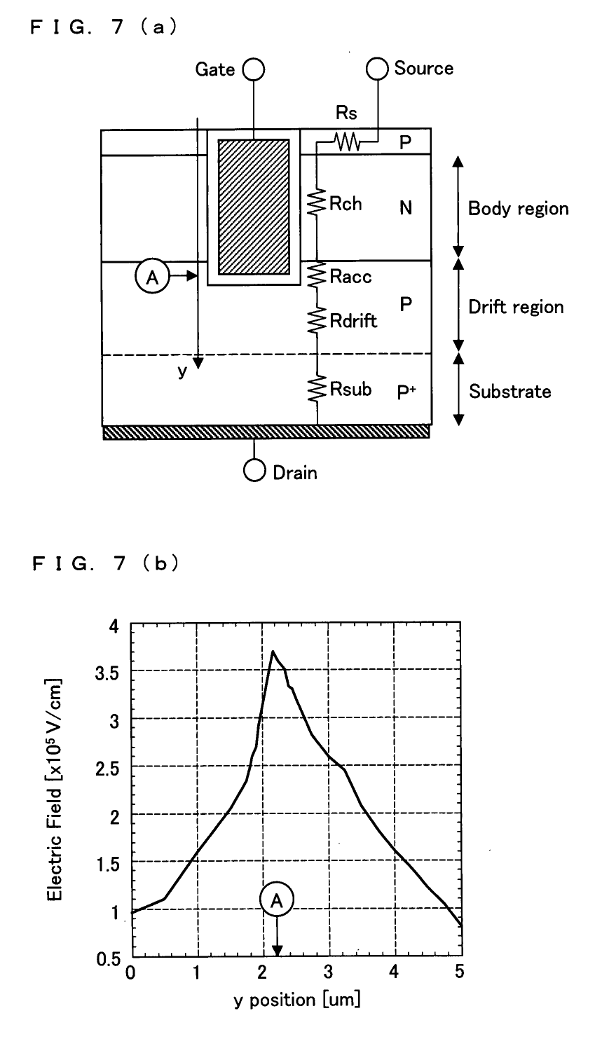

The physical location of respective components of the Trench MOSFET, and meaning of the different components of the ON resistance are illustrated in FIG. 7(a). In this figure, Rs is the resistance of the diffusion and contact resistance component of the source region, Rch is the resistance of the induced MOSFET channel, Racc is the resistance of the accumulation region of the gate and the drain, Rdrift is the resistance of the low-doped drain region, and Rsub is the resistance of the highly doped drain (substrate) region.

The relationship described by the following formula is satisfied between the ON resistance (Rₒₙ) of the MOSFET and the components of the resistances shown in FIG. 7(a):
R_{ON}=Rs+Rch+Racc+Rdrift+Rsub.

FIG. 7(b) is a graph showing an electric field along the arrow y (an upper end surface close to the gate is 0, and the direction of the arrow is positive) shown in FIG. 7(a). As shown in this figure, the electric field intensity becomes maximum in the vicinity of the bottom of the trench, indicated by A in FIG. 7(a). Breakdown is likely to occur in this area.

In general, there is tradeoff between Ron and BVdss since to get high breakdown voltage (BVdss) in the Trench MOSFET, a low impurity doped drift region is needed. This results in an increase in the resistance (Rdrift) of the lightly-doped drain region and therefore results in an increase in the ON resistance (R_{ON}) of the Trench MOSFET.

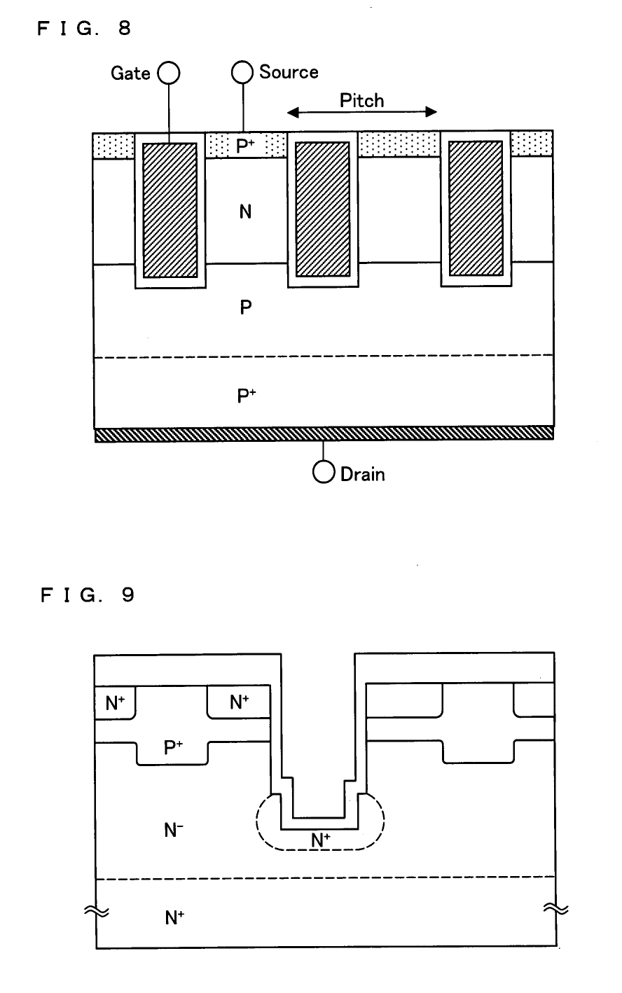

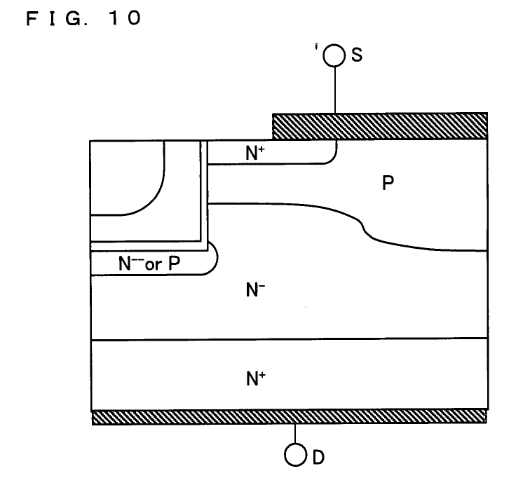

With conventional techniques, reduction of the ON resistance of the Trench MOSFETs is achieved by cell pitch reduction, as shown in FIG. 8. Further, a technique to increase the breakdown voltage is to optimize the depth and the shape of the trench, as shown in FIG. 9 (see Patent Reference 1, for example). FIG. 10 shows an example of the MOSFET structure and doping profile to reduce the breakdown voltage degradation at the corner of the trench (see Patent Reference 2, for example).

The current art, represented by Patent References 1 and 2, intend to reduce the maximum electric field intensity at the corner of the trench indicated as A in FIG. 7(b).

[Patent Reference 1] Specification of U.S. Pat. No. 5,168,331 (published on Dec. 1, 1992)

[Patent Reference 2] Specification of U.S. Pat. No. 4,893,160 (published on Jan. 9, 1990)

[Non-Patent Reference 1] Krishna Shenai, “Optimized Trench MOSFET Technologies for Power Devices”, IEEE Transactions on Electron Devices, vol. 39, no. 6, pp. 1435-1443, June 1992.

### DISCLOSURE OF INVENTION

The prior art techniques in relation to the Trench MOSFET have the following problems (a) and (b):
(a) Reduction of the ON resistance is mostly achieved by cell pitch reduction that may be limited by photolithography/etching processing; and
(b) Increase of the breakdown voltage requires special trench shaping and/or additional fabrication steps that complicate process, increase manufacturing cost and reduce yield.

The present invention is in view of the foregoing problems, and has as an object to realize a Trench MOSFET with increased breakdown voltage without causing the foregoing problems.

The Trench (vertical) MOSFET is arranged in such a manner that a closer part to a substrate is a drain, an opposite part to the substrate is a source, and a gate electrode is deposited in a trench region. This results in that an end part (part close to the drain) of the gate electrode in the trench region of the Trench MOSFET is in contact with a high impurity concentration region of the drain, bringing a problem of voltage-resistance between a channel region and this drain region. In view of this problem, conventional Trench MOSFET includes a drift region of low concentration (medium concentration).

However, providing the drift region as described above brings a new problem of increase in ON resistance. The conventional techniques discussed above are in view of these problems. In the conventional technique, tradeoff between the voltage-resistance and the ON resistance is taken into consideration in setting conditions with various adjustments.

On the contrary, with the Trench MOSFET of the present invention, the voltage-resistance is improved by electric-field reduction at the end part of the gate deposited. Improvement in voltage-resistance allows the drift region to be small. This has an effect of reduction in the ON resistance. As a result, effect of reduction in size (vertical and horizontal directions) of the Trench MOSFET is obtained. Especially the size reduction in horizontal direction is advantageous because this allows higher density of the Trench MOSFET.

To solve the above problems, the Trench MOSFET of the present invention includes: a semiconductor substrate including a highly-doped drain region of a first conductivity type, a lightly-doped drain region of the first conductivity type, a channel body region of a second conductivity type, and a source region of the first conductivity type; a trench region being formed on the semiconductor substrate; an insulator layer formed on a bottom surface and a sidewall of the trench; and a gate electrode provided within the trench region. The highly-doped drain region, the lightly-doped drain region, the channel body region, and the source region are adjacently formed in this order. The insulator layer includes, on the sidewall of the trench between the lightly-doped drain region and the gate electrode, an electric-field reducer that is thicker than a thickness of the insulator layer between the gate electrode and the channel body region.

The semiconductor substrate of the Trench MOSFET of the present invention may be Silicon.

With this structure, a Trench MOSFET with increased breakdown voltage is realized, compared to conventional Trench MOSFET. The Trench MOS transistor of the present invention includes, between the lightly-doped drain region and the gate electrode, the insulator layer (electric-field reducer) thicker than the rest of the regions. This improves voltage-resistance in the vicinity of the bottom of the trench.

The thickness of the insulator film on the sidewall of the trench region, which insulator film covers the end (bottom) part of the gate electrode in the vicinity of the bottom of the trench region, is made thicker than the thickness of the insulator film between the gate electrode and the channel body region. This improves voltage-resistance in the lightly-doped drain region in the vicinity of the bottom of the trench region, allowing lightly-doped drain region, which is the drift region, to become small. It thus becomes possible to increase the breakdown voltage, to reduce the ON resistance of the Trench MOSFET, and to reduce the size of the Trench MOSFET.

It is preferable that the thickness of the electric-field reducer be 1.2 to 3 times the thickness of the insulator layer formed between the gate electrode and the channel body region. To improve voltage-resistance of the Trench MOSFET, it is suitable to include the electric-field reducer satisfying this relationship and to form the insulator layer at the trench region.

It is preferable that the gate insulator formed at the bottom of the trench have a thickness equal to the thickness of the electric-field reducer. This makes it possible to improve voltage-resistance in the vicinity of the bottom of the trench region, in the direction of the bottom surface as well as in the direction of the sidewall.

It is preferable that the electric-field reducer be formed only between the lightly-doped drain region and the gate electrode, and is not formed between the gate electrode and the channel body region. With this structure, the electric field in the vicinity of the bottom of the trench is reduced, so that voltage-resistance of the Trench MOSFET improves.

It is preferable that the thickness of the insulator layer have gradual and smooth transition from thickness Tox between the gate electrode and the channel body region to thickness Tsox of the electric-field reducer, and satisfy the relationship below
0.6<(Tsox−Tox)/Δy<1.2
(where, Δy is the length of the transition region in which the thickness of the insulator layer changes from Tox to Tsox).

With this structure, the insulator layer forms no corner, so that increase in the density of the electric field at corners is avoided. Further, if the level of the transition of the thickness of the insulator layer from Tox to Tsox satisfies the relationship of the formula above, increase in the density of the electric field due to the level of the transition of the thickness is avoided.

The above-described Trench MOSFET of the present invention is produced by a fabrication method including the steps of: forming a SiO₂ layer/SiN layer stack in such a manner that a sidewall and a bottom surface of a trench region are in contact with the SiO₂ layer; etching to remove the SiO₂ layer/SiN layer stack at the bottom of the trench region; etching the semiconductor substrate at the bottom of the trench region where the SiO₂ layer/SiN layer stack is removed; and thermally oxidizing, with the use of the SiO₂ layer/SiN layer stack as oxidation prevention mask on the semiconductor substrate, the semiconductor substrate exposed by the etching.

With this method, the semiconductor substrate at a part of the bottom surface of the trench region, from which part the SiO₂ layer/SiN layer stack is removed, is etched to “a depth substantially equal to” the length of the electric-field reducer, which is to be formed later, along the direction of the depth of the trench region, whereby a region where the electric-field reducer is to be formed is defined. Then, the region exposed by the etching is thermally oxidized so that the electric-field reducer is formed on the bottom surface of the trench region and the nearby sidewall of trench region. Thus, with the method, the Trench MOSFET of the present invention is fabricated easily and simply.

It is preferable in the method that the thickness of the SiO₂ layer in the SiO₂/SiN stack be 0.2 to 0.6 times the thickness of the electric-field reducer, and the thickness of the SiN layer in the SiO₂/SiN stack is 0.2 to 1 times the thickness of the electric-field reducer.

As the foregoing describes, the Trench MOSFET of the present invention includes the electric-field reducer between the lightly-doped drain region and the gate electrode. This realizes a Trench MOSFET with reduced electric field intensity at the bottom of the trench and increased breakdown voltage.

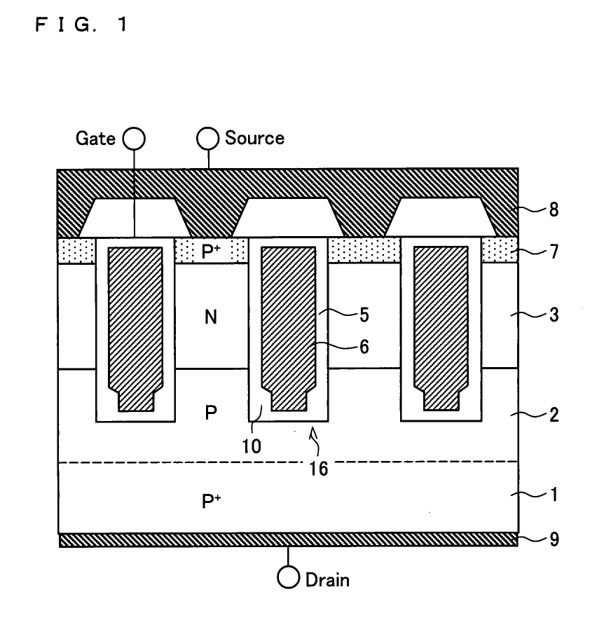

### BRIEF DESCRIPTION OF DRAWINGS

[FIG. 1]

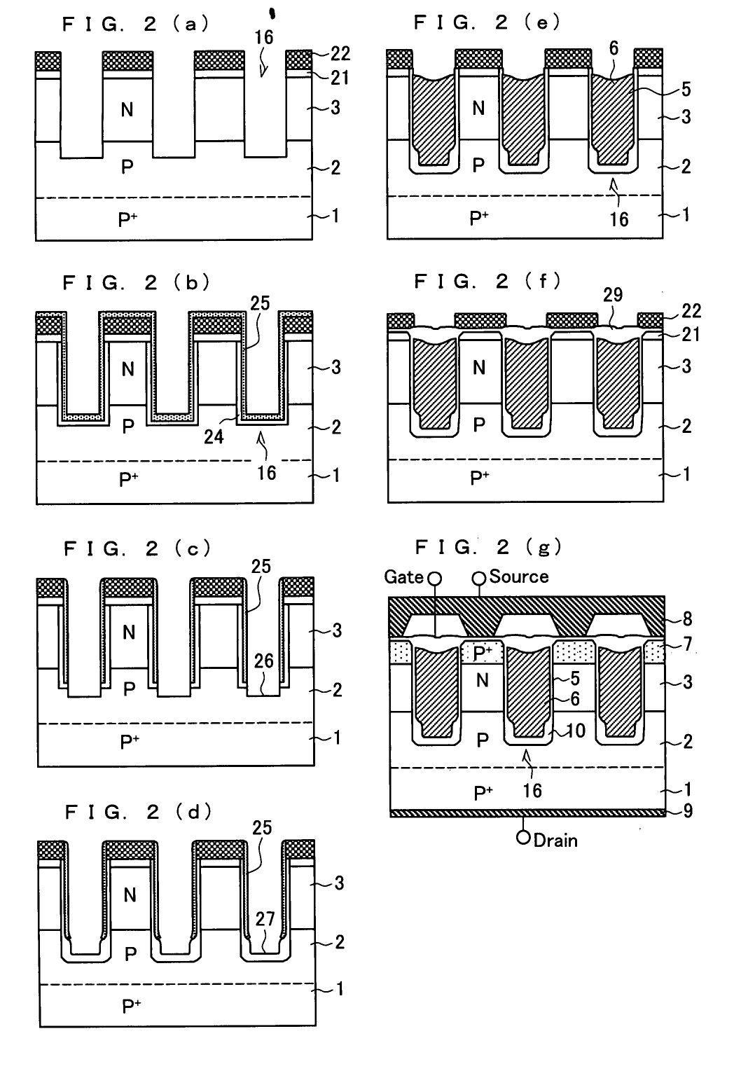

This is a cross-sectional diagram schematically showing a basic structure of a Trench MOSFET in accordance with an embodiment of the present invention.

[FIG. 2(a)]

This is a cross-sectional diagram showing a schematic structure of the Trench MOSFET to illustrate the fabrication sequence of the Trench MOSFET step-by-step, in accordance with the present embodiment.

[FIG. 2(b)]

This is a cross-sectional diagram showing a schematic structure of the Trench MOSFET to illustrate the fabrication sequence of the Trench MOSFET step-by-step, in accordance with the present embodiment.

[FIG. 2 (c)]

This is a cross-sectional diagram showing a schematic structure of the Trench MOSFET to illustrate the fabrication sequence of the Trench MOSFET step-by-step, in accordance with the present embodiment.

[FIG. 2 (d)]

This is a cross-sectional diagram showing a schematic structure of the Trench MOSFET to illustrate the fabrication sequence of the Trench MOSFET step-by-step, in accordance with the present embodiment.

[FIG. 2 (e)]

This is a cross-sectional diagram showing a schematic structure of the Trench MOSFET to illustrate the fabrication sequence of the Trench MOSFET step-by-step, in accordance with the present embodiment.

[FIG. 2 (f)]

This is a cross-sectional diagram showing a schematic structure of the Trench MOSFET to illustrate the fabrication sequence of the Trench MOSFET step-by-step, in accordance with the present embodiment.

[FIG. 2 (g)]

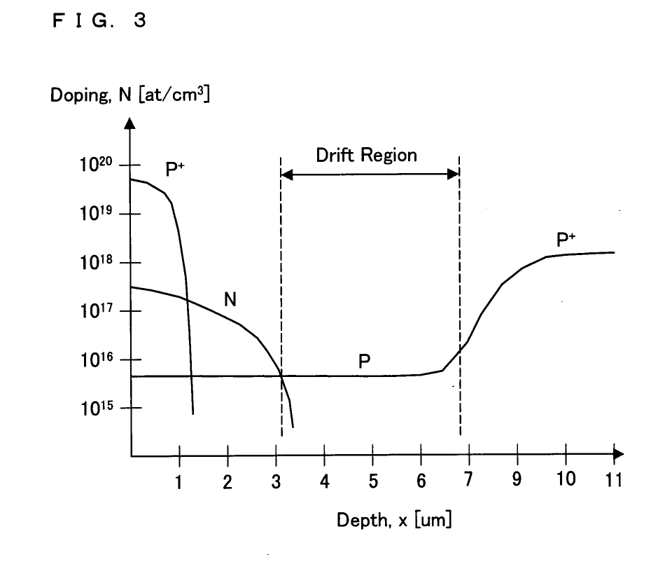

This is a cross-sectional diagram showing a schematic structure of the Trench MOSFET to illustrate the fabrication sequence of the Trench MOSFET step-by-step, in accordance with the present embodiment.

[FIG. 3]

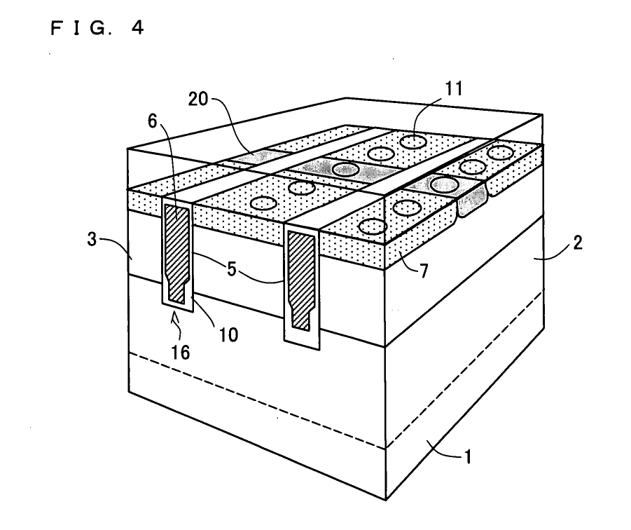

This is a graph showing a typical doping profile of a semiconductor wafer of the Trench MOSFET of the present embodiment.

[FIG. 4]

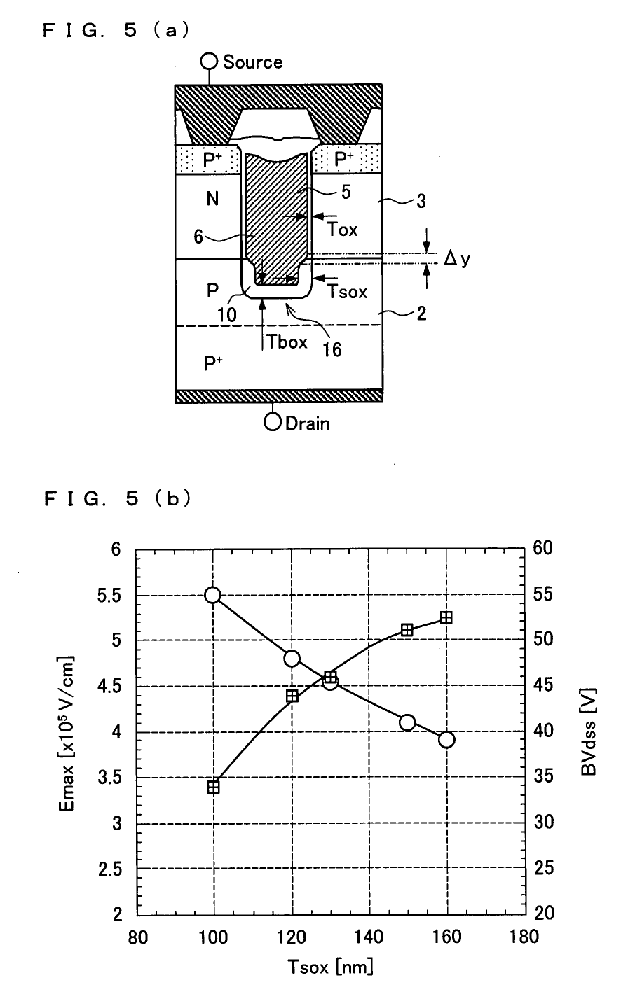

This is a schematic perspective view to illustrate an arrangement of the channel body diffusion of the Trench MOSFET of the present embodiment.

[FIG. 5(a)]

This is a cross-sectional diagram of the Trench MOSFET of the present embodiment to illustrate a thickness of a gate insulator formed on a side wall of the trench.

[FIG. 5(b)]

This is a graph showing an effect of thickness Tsox in a breakdown voltage.

[FIG. 6(a)]

This is a cross-sectional diagram schematically showing a fabrication sequence of a prior art Trench MOSFET, showing a step in which an Epi layer (n-epi) and a body region (diffusion, p-base) are formed.

[FIG. 6(b)]

This is a cross-sectional diagram schematically showing a fabrication sequence of a prior art Trench MOSFET, showing a step in which a SiO₂ opening is formed.

[FIG. 6(c)]

This is a cross-sectional diagram schematically showing a fabrication sequence of a prior art Trench MOSFET, showing a step in which the trench is fabricated with the opening in FIG. 6(b) to define the etching.

[FIG. 6(d)]

This is a cross-sectional diagram schematically showing a fabrication sequence of a prior art Trench MOSFET, showing a step in which the trench is filled with polysilicon deposition and etched back.

[FIG. 6(e)]

This is a cross-sectional diagram schematically showing a fabrication sequence of a prior art Trench MOSFET, showing a step in which oxide is etched, and N+°(source) and P+ (body) are implanted.

[FIG. 6(f)]

This is a cross-sectional diagram schematically showing a fabrication sequence of a prior art Trench MOSFET, showing a step in which Interlevel dielectric deposition and metallization are carried out.

[FIG. 7(a)]

This is a cross-sectional diagram showing physical arrangement of components of the prior art P-channel Trench MOSFET, and components of ON resistance.

[FIG. 7(b)]

This is a graph showing an electric field along arrow y in FIG. 7(a).

[FIG. 8]

This is a cross-sectional diagram of the prior art P-channel Trench MOSFET showing a periodic structure and a cell pitch.

[FIG. 9]

This is a cross-sectional diagram showing a structure of the prior art P-channel Trench MOSFET in which a depth and a shape of the trench are optimized to increase breakdown voltage.

[FIG. 10]

This is a cross-sectional diagram showing a prior art MOSFET structure and doping profile to reduce the breakdown voltage degradation at the corner of the trench.

### EXPLANATION OF REFERENCE

1 substrate (highly-doped drain region)
2 epitaxial layer (lightly-doped drain region)
3 body region (channel body region)
5 gate dielectric (insulator layer)
6 gate electrode
7 highly-doped source region (source region)
10 electric-field reducer
16 trench
24 SiO₂ layer
25 SiN layer

### BEST MODE FOR CARRYING OUT THE INVENTION

The following describes an embodiment of a Trench MOSFET of the present invention, with reference to figures.

[Structure of Trench MOSFET]

FIG. 1 is a cross-sectional diagram schematically showing a basic structure of the Trench MOSFET of the present embodiment. As shown in this figure, a Trench MOSFET (Metal Oxide Semiconductor Field Effect Transistor) of the present embodiment is a semiconductor substrate (The semiconductor substrate is a laminate of a substrate 1, an epitaxial layer 2, a body region 3, and a source diffusion 7, all of which will be described later. Hereinafter, the semiconductor substrate will be referred to as “semiconductor wafer” sometimes.) having a trench 16. The Trench MOSFET includes a substrate 1 of a first conductivity type (P-type in the present embodiment), a lightly-doped drain region (drift region) 2 of the first conductivity type, a body region (channel body region) 3 of a second conductivity type (N-type in the present embodiment), and a highly-doped source region (source region) 7. The substrate 1 is formed on a surface of the semiconductor wafer, which surface is close to the drain 9. The lightly-doped drain region 2 is formed in contact with the substrate 1. The body region 3 is formed between the epitaxial layer 2 and the top metallization 8, which is on a source side of the semiconductor wafer. The highly-doped source region 7 is formed at the source side (uppermost layer) of the semiconductor wafer. The highly-doped source region 7 is formed between the metallization 8 and the body region 3 so as to be in contact with the top metallization 8 and the body region 3.

A gate insulator (insulator layers gate-induced channel) 5 is formed on a side wall of the trench 16 formed in the semiconductor wafer. The trench 16 extends from a surface of the semiconductor wafer, which surface is close to the highly doped source region 7, in such a way as to interrupt the highly doped source region 7 and pass through the body region 3. The bottom of the trench 16 reaches the epitaxial layer 2 and is arranged within the epitaxial layer 2. Therefore, the length of the channel of the Trench MOSFET of the present embodiment is determined by the difference between the depth of the body region 3 from the surface close to the highly doped source region 7 and the depth of a junction with the source region in the highly doped source region 7 from the surface close to the highly doped source region 7.

The gate insulator 5 is deposited or grown on the sidewalls (vertical walls) and the bottom of the trench 16. The gate electrode 6 is deposited within the trench 16 and separated from the semiconductor wafer by the gate insulator 5. The gate insulator 5 has essentially two regions of different thicknesses. The gate insulator 5 includes, at a region where the epitaxial layer 2 and the gate electrode 6 overlap, an electric-field reducer 10, which is thicker than a region where the body region 3 and the gate electrode 6 overlap.

The trench 16 is formed in the shape of depression in the semiconductor wafer. The shape of the sidewall of the trench 16, which sidewall is in contact with the semiconductor wafer, is essentially perpendicular to a surface of the highly doped source region 7, which surface is close to the source region.

As described above, the epitaxial layer 2 is formed next to the substrate 1 in the Trench MOSFET of the present embodiment. The body region 3 of the Trench MOSFET is opposite in polarity to the epitaxial layer (drift region) 2. The gate electrode 6 and the gate insulator 5 both control induction of the Trench MOSFET. The highly doped source region 7 is contacted by the top metallization 8, and the drain 9 is formed by metallization.

The gate insulator 5 including the electric-field reducer 10 is formed on the sidewall and the bottom of the trench 16. To reduce the electric-field strength in the vicinity of the bottom of the trench 16, the electric-field reducer 10 is made thicker at the overlap with the epitaxial layer 2 than at the overlap with the body region 3. The electric-field reducer 10 is formed on the gate insulator 5 to optimize the relationship between the ON resistance and increase of the breakdown voltage.

In the present embodiment, a P-type MOSFET is described, but it will be obvious for those skilled in the art that the present invention is also applicable to an N-type MOSFET.

[Fabrication Sequence of Trench MOSFET]

FIGS. 2(a) to 2(g) are cross-sectional diagrams each showing a schematic structure of the Trench MOSFET at respective steps to illustrate the fabrication sequence of the Trench MOSFET of the present embodiment step-by-step. The starting silicon substrate 1 is P-type doped with a typical resistivity of 0.01 to 0.0050 Ω·cm and a thickness of 500 to 650 μm. The final thickness of the substrate 1 after device fabrication is reduced to approximately 100 to 150 μm by back lapping.

On top of the P+ substrate 1, a P layer doped more lightly than the substrate 1 is grown by epitaxis to form the epitaxial layer (Epi layer) 2. A thickness Xepi and resistivity ρₑₚᵢ of the epitaxial layer 2 formed in the foregoing way are set in a manner that depends on final electrical characteristics expected to the Trench MOSFETs fabricated. Typically, to reduce the ON resistance of the Trench MOSFET, the resistance of the epitaxial layer 2 should be low, but there is a tradeoff between the breakdown voltage and the lower resistance of the epitaxial layer 2. A typical doping profile of the semiconductor wafer constituted of the P+-type highly doped source region 7, the N-type body region 3, the P-type epitaxial layer 2, and the P+-type substrate 1 is shown in FIG. 3.

The body region 3 of the Trench MOSFET of the present embodiment is an N-type semiconductor. The body region 3 is fabricated by implanting Phosphorus atoms to achieve a doping concentration of between 5×10¹⁶ to 7×10¹⁷ [atoms/cm³] at the surface of the silicon. The N-type body region 3 is designed to achieve a PN junction with the epitaxial layer 2 at a depth Xn of between 2 to 5 μm depending on the electrical characteristics of the Trench MOSFET. As an example, for a 40V operation Trench MOSFET, Xn is typically 2 to 3 μm and the thickness of the epitaxial layer 2 is approximately 7 μm.

On top of the body region 3 (source side of the semiconductor wafer), a SiO₂ layer 21 and a CVD oxide layer 22 are deposited. The SiO₂ layer 21 and the CVD oxide layer 22 are patterned using well known photo-etching techniques to define the trench 16. Using the SiO₂ layer 21/CVD oxide layer 22 stack as etching mask, the trench 16 is formed, as illustrated in FIG. 2(a).

As shown in FIG. 2(a), after the trench 16 is formed by etching, a surface oxide (SiO₂) is thermally grown to a thickness of 5 to 10 nm, and then the surface oxide is removed to remove damage to the semiconductor vertical surface introduced by the etching process of forming the trench 16.

The following describes a process of forming the electric-field reducer 10 in the vicinity of the bottom of the gate electrode 6, which electric-field reducer 10 continues from a graded surface as shown in FIG. 1. A SiO₂ layer 24/SiN layer 25 stack is formed covering the sidewall and the bottom surface of the trench 16, as shown in FIG. 2(b). The thicknesses of the SiO₂ layer 24/SiN layer 25 stack are typically: the SiO₂ layer 24 is approximately 10 nm to 30 nm; and the SiN layer 25 is approximately 20 nm to 60 nm. Using the SiO₂ layer 24/SiN layer 25 stack as a mask, anisotropic dry etching is used to remove the SiO₂ layer 24/SiN layer 25 stack at the bottom surface of the trench 16 and to remove the Si of the epitaxial layer 2 to a depth of approximately 50 nm to 200 nm, whereby a Si region 26 that is not covered by the SiN layer 25 is formed on the sidewall and the bottom surface of the trench 16, as shown in FIG. 2(c).

As described above, after forming the SiO₂ layer 24/SiN layer 25 stack on the sidewall and the bottom surface of the trench 16 with the bottom surface reaching the epitaxial layer 2, the SiO₂ layer 24/SiN layer 25 stack is removed so as to form the Si region 26. As a result, the SiN layer 25 covers the sidewall of the trench 16 so as to cover the body region 3 and a part of the epitaxial layer 2, which part is close to the body region 3, as shown in FIG. 2(c). Further, the Si region 26, not covered by the SiN layer 25, is formed at a part of the bottom surface and the sidewall of the trench 16, which part is contiguous with the epitaxial layer 2, as shown in FIG. 2(c).

As described above, the Si region 26, formed by etching the bottom surface of the trench 16, is thermally oxidized so that the oxide 27 is formed in a manner that depends on the thickness of the electric-field reducer 10 (see FIG. 1) of the gate insulator 5, as shown in FIG. 2(d). The thickness of the electric-field reducer 10 depends on the desired breakdown voltage of the Trench MOSFET to be fabricated. After this oxidation, the SiN layer 25 and the SiO₂ layer 24 are removed. At this time, a thickness equivalent to the thickness of the SiO₂ layer 24 is removed from the oxide layer 27.

Next, the gate insulator 5 is thermally grown on the sidewall and the bottom of the trench 16, and the trench 16 is filled with a gate PolySilicon to form the gate electrode 6. In the present embodiment, a POCl₃ doping source was used to dope the Polysilicon with Phosphorus. After doping, the Polysilicon was removed from the surface of the semiconductor wafer, in this way, the Polysilicon only remains filling the trench 16, as shown in FIG. 2(e).

Using the CVD oxide layer 22/SiO₂ layer 21 stack as oxidation mask, the semiconductor wafer is thermally oxidized. This results in oxide isolation layer 29 on top of the gate electrodes 6 at the trenches 16, as shown in FIG. 2(f).

FIG. 4 is a schematic perspective view of the Trench MOSFET of the present embodiment to illustrate the arrangement of the channel body diffusion 20. The source diffusion 7 and the channel body diffusion 20 are formed by respective photoresist masking and ion implantation in a well-known manner. The source diffusion 7, which is P⁺-type, is formed by implanting P-type dopants (¹¹B⁺ or BF₂⁺) to a dose of approximately 1×10¹⁵ to 3×10¹⁵ to form a junction at a depth of between 0.2 to 0.5 μm. In like way, the channel body diffusion 20 is formed by implanting N-type dopants (³¹P⁺ or ⁷⁵As⁺) to a dose of approximately 1×10¹⁵ to 3×10¹⁵ to form a junction at a depth of between 0.2 to 0.5 μm.

As an alternative, the silicidation process could be used on the P-type source diffusion 7 and the N-type channel body diffusion 20.

Final inter-level dielectric layer, contacts 11, and top metallization 8 (see FIG. 1) are formed by a conventional publicly-known processing typical of IC fabrication.

After thinning the semiconductor wafer to a thickness of 100 μm to 150 μm by back lapping, a metallization stack is applied to the back of the wafer (substrate 1) and alloyed by treatment in forming gas at 430° C. for 10 min.

The Trench MOSFET of the present embodiment in FIG. 2(g) is fabricated in the foregoing manner.

For instance, for a P-channel Trench MOSFET specified to support a maximum operating voltage Vmax=50V, the thickness of the gate insulator 5 would be approximately 80 nm. To achieve a threshold voltage Vth=−2V, the body region 3, which is the channel region, would be doped with Phosphorus to achieve a doping concentration of 6×10¹⁶ to 2×10¹⁷ [ions/cm³].

By using the above structure of the Trench MOSFET of the present invention, the following design parameter may be used in regard to the thickness Tsox of the electric-field reducer 10 (see FIG. 1) formed on the sidewall of the bottom of the trench 16. FIG. 5(a) is a cross-sectional diagram illustrating the thickness of the gate insulator 5 formed on the sidewall of the trench 16. As shown in this figure, the thickness of the gate insulator 5 in a region between the gate electrode 6 and the body region 3 is indicated as Tox, and the thickness of the gate insulator 5 in a region between the gate electrode 6 and the epitaxial layer 2 is indicated as Tsox. Tox and Tsox each indicate a thickness of the gate insulator 5 in a region where the thickness is substantially uniform. A region between Tox and Tsox, in which region the thickness varies, is not taken into consideration in evaluating Tox and Tsox.

The effect of Tsox in the breakdown voltage is illustrated in FIG. 5(b), for a device design to obtain breakdown voltage BVdss=50V with a doping ion concentration of the epitaxial layer 2, which is the drift region, of 3×10¹⁶[ions/cm³]. As shown in this figure, as Tsox is made thicker than Tox (80 nm), the maximum electric field strength (Emax, indicated by “O” in the figure) is reduced and the breakdown voltage (BVdss, indicated by “□” with “+” inside) increases. The increase of breakdown voltage saturates for Tsox>160 nm.

It is preferable that the thickness of the gate insulator 5 including the electric-field reducer 10 formed on the sidewall of the trench 16 have gradual and smooth transition from Tox to Tsox. With this structure, formation of a corner is prevented at the gate insulator 5, so that the density of the electric-field is prevented from increasing at the corners. The slope of the thickness from the Tox to Tsox is defined by the following formula
Slope=(Tsox−Tox)/Δy
where Δy is the length of the transition region of the thickness of the gate insulator 5 from Tox to Tsox, as shown in FIG. 5(a).

It is empirically recommended that the slope defined by the above formula satisfy the relation 0.6<Slope<1.2. This slope can be achieved by adjusting the relative thicknesses of the SiO₂ layer 24/SiN layer 25 stack (see FIGS. 2(b) to 2(d)) in relation to the final thickness Tsox of the electric-field reducer 10 in the fabrication sequence of the Trench MOSFET. As is well known in the art, the rigidity of the SiN layer 25 depends on its thickness. The slope of the gate insulator 5 is controllable by controlling the rigidity of the SiN layer 25.

Further, it is preferable that the thickness Tbox (see FIG. 5(a)) of the gate insulator 5 at the bottom of the trench 16 be equal to the thickness Tsox of the electric-field reducer 10 formed on the sidewall of the bottom of the trench 16. In this way, voltage-resistance improves in the vicinity of the bottom of the trench, in the direction of the bottom surface as well as in the direction of the sidewall.

The foregoing Trench MOSFET of the present invention has the following effects. (a) The breakdown voltage of the Trench MOSFET increases. (b) Higher breakdown voltage is attained with a thinner gate insulator, compared to conventional cases, resulting in higher ON current and therefore a reduction in ON resistance. (c) As total result, smaller chip size and cost reduction in the Trench MOSFET are attained.

The present invention is not limited to the description of the embodiments above, but may be altered by a skilled person within the scope of the claims. An embodiment based on a proper combination of technical means disclosed in different embodiments is encompassed in the technical scope of the present invention.

### INDUSTRIAL APPLICABILITY

A Trench MOSFET of the present invention is applicable to switching applications and the like.

1. A Trench MOSFET, comprising:
a semiconductor substrate including a highly-doped drain region of a first conductivity type, a lightly-doped drain region of the first conductivity type, a channel body region of a second conductivity type, and a source region of the first conductivity type;
a trench region being formed on the semiconductor substrate;
an insulator layer formed on a bottom surface and a sidewall of the trench; and
a gate electrode provided within the trench region,
the highly-doped drain region, the lightly-doped drain region, the channel body region, and the source region being adjacently formed in this order, and
the insulator layer including, on the sidewall of the trench between the lightly-doped drain region and the gate electrode, an electric-field reducer that is thicker than a thickness of the insulator layer between the gate electrode and the channel body region.

2. The Trench MOSFET of claim 1 in which the semiconductor substrate is Silicon.

3. The Trench MOSFET of claim 1 in which the thickness of the electric-field reducer is 1.2 to 3 times the thickness of the insulator layer formed between the gate electrode and the channel body region.

4. The Trench MOSFET of claim 1 in which the gate insulator formed at the bottom of the trench has a thickness equal to the thickness of the electric-field reducer.

5. The Trench MOSFET of claim 1 in which the electric-field reducer is formed only between the lightly-doped drain region and the gate electrode, and is not formed between the gate electrode and the channel body region.

6. The Trench MOSFET of claim 1 in which the thickness of the insulator layer has gradual and smooth transition from thickness Tox between the gate electrode and the channel body region to thickness Tsox of the electric-field reducer, and satisfy the relationship below
0.6<(Tsox−Tox)/Δy<1.2
(where, Δy is the length of the transition region in which the thickness of the insulator layer changes from Tox to Tsox).

7. A method of fabricating a Trench MOSFET, comprising:
a semiconductor substrate including a highly-doped drain region of a first conductivity type, a lightly-doped drain region of the first conductivity type, a channel body region of a second conductivity type, and a source region of the first conductivity type;
a trench region being formed on the semiconductor substrate;
an insulator layer formed on a bottom surface and a sidewall of the trench; and
a gate electrode provided within the trench region,
the highly-doped drain region, the lightly-doped drain region, the channel body region, and the source region being adjacently formed in this order, and
the insulator layer including, on the sidewall of the trench between the lightly-doped drain region and the gate electrode, an electric-field reducer that is thicker than a thickness of the insulator layer between the gate electrode and the channel body region;
the method comprising the steps of:
forming a SiO2 layer/SiN layer stack in such a manner that a sidewall and a bottom surface of a trench region are in contact with the SiO2 layer;
etching to remove the SiO2 layer/SiN layer stack at the bottom of the trench region;
etching the semiconductor substrate at the bottom of the trench region where the SiO2 layer/SiN layer stack is removed; and
thermally oxidizing, with the use of the SiO2 layer/SiN layer stack as oxidation prevention mask on the semiconductor substrate, the semiconductor substrate exposed by the etching.

8. The method of claim 7 in which the thickness of the SiO2 layer in the SiO2/SiN stack is 0.2 to 0.6 times the thickness of the electric-field reducer, and the thickness of the SiN layer in the SiO2/SiN stack is 0.2 to 1 times the thickness of the electric-field reducer.
